(19) United States
(12) Patent Application Publication
(10) Pub. No.: US 2019/0333797 A1
(43) Pub. Date: Oct. 31, 2019

(54) APPARATUS AND METHOD FOR OPENING SNAP-SHOT CASES

(71) Applicant: STEK CO., LTD, Taichung City (TW)

(72) Inventor: Ming-Sheng Chen, Taichung City (TW)

(21) Appl. No.: 15/967,594

(22) Filed: Apr. 30, 2018

(51) Int. Cl. H01L 21/673; G03F 1/66

(52) U.S. Cl. CPC H01L 21/67373; G03F 1/66; H01L 21/67359

(57) ABSTRACT

A case-opening apparatus is operable to open a snap-shot case. The includes a first shell, a second shell pivotally connected to the first shell, a tab formed on one of the first and second shells, and an elastic hook formed on the other one of the first and second shells and engageable with the tab. The case-opening apparatus includes a holding unit, a lifting unit and a key-operating unit. The holding unit includes a holder for holding the first shell. The lifting unit is located above the holding unit and includes a pivotable frame and a grasper connected to the pivotable frame and operable to grasp the second shell. The key-operating unit is located in the vicinity of the holding unit and includes a key operable to pivot the elastic hook relative to the tab.

### BACKGROUND OF INVENTION

### 1. Field of Invention

The present invention relates to snap-shot cases and, more particularly, to an apparatus and method for opening snap-shot cases.

### 2. Related Prior Art

In lithography for making semiconductor products, masks are important elements for making integrated circuits on wafers. Yields could be reduced and costs increased if the integrated circuits are jeopardized due to contamination on the masks. Hence, the masks should be kept clean in operation, transportation and storage. To this end, the masks are inserted in very clean cases in transportation and storage.

Referring to FIGS. 1 and 2, in transportation and storage, a mask (not shown) can be inserted in a typical snap-shot case 100 that includes a first shell 110 and a second shell 120. An edge of the first shell 110 is pivotally connected to an edge of the second shell 110 so that the first and second shells 110 and 120 can be pivoted to and from each other to close and open the snap-shot case 100. A snap-shot lock 150 is used to lock the first and second shells 110 and 120 to each other. The snap-shot lock 150 includes an elastic hook 151 formed at an opposite edge of the first shell 110 and a tab 152 formed at an opposite edge of the second shell 120. Referring to FIG. 2, the elastic hook 151 can be engaged with the tab 152 to lock the first and second shells 110 and 120 to each other. Referring to FIG. 1, the elastic hook 151 can be disengaged from the tab 152 to allow the pivoting of the first and second shells 110 and 120 from each other.

The structure of the snap-shot case 100 is simple without providing any portion for effective holding or clamping. It requires a worker to disengage the elastic hook 151 from the tab 152. Hence, it is difficult to automatically open the snap-shot case 100 in an optical inspection machine, a mask-cleaning machine or a mask-storage machine.

The present invention is therefore intended to obviate or at least alleviate the problems encountered in prior art.

### SUMMARY OF INVENTION

It is an objective of the present invention to provide an apparatus and method for improving the efficiency in opening a snap-shot case that contains a mask.

It is another objective of the present invention to provide an apparatus and method for improving the cleanness of a mask while opening a snap-shot case that contains the mask.

To achieve the foregoing objectives, the apparatus is operable to open a snap-shot case. The includes a first shell, a second shell pivotally connected to the first shell, a tab formed on one of the first and second shells, and an elastic hook formed on the other one of the first and second shells and engageable with the tab. The case-opening apparatus includes a holding unit, a lifting unit and a key-operating unit. The holding unit includes a holder for holding the first shell. The lifting unit is located above the holding unit and includes a pivotable frame and a grasper connected to the pivotable frame and operable to grasp the second shell. The key-operating unit is located in the vicinity of the holding unit and includes a key operable to pivot the elastic hook relative to the tab.

Other objectives, advantages and features of the present invention will be apparent from the following description referring to the attached drawings.

### BRIEF DESCRIPTION OF DRAWINGS

The present invention will be described via detailed illustration of the preferred embodiment referring to the drawings wherein:

FIG. 1 is a perspective view of a typical snap-shot case;

FIG. 2 is an enlarged partial view of the snap-shot case in another position than shown in FIG. 1;

FIG. 3 is a perspective view of a case-opening apparatus according to the preferred embodiment of the present invention, operable for opening the typical snap-shot case shown in FIG. 2;

FIG. 4 is an enlarged partial view of the case-opening apparatus shown in FIG. 3;

FIG. 5 is a flow chart of a case-opening method executed in the case-opening apparatus shown in FIG. 3;

FIG. 6 is a perspective view of the case-opening apparatus in another position than shown in FIG. 3;

FIG. 7 is a perspective view of the case-opening apparatus in another position than shown in FIG. 6;

FIG. 8 is a cross-sectional view of the case-opening apparatus shown in FIG. 7;

FIG. 9 is an enlarged partial view of the case-opening apparatus shown in FIG. 8;

FIG. 10 is another cross-sectional view of the case-opening apparatus shown in FIG. 7;

FIG. 11 is a perspective view of the case-opening apparatus in another position than shown in FIG. 7; and

FIG. 12 is a perspective view of the case-opening apparatus shown in FIG. 3, used to open another snap-shot case of a different size.

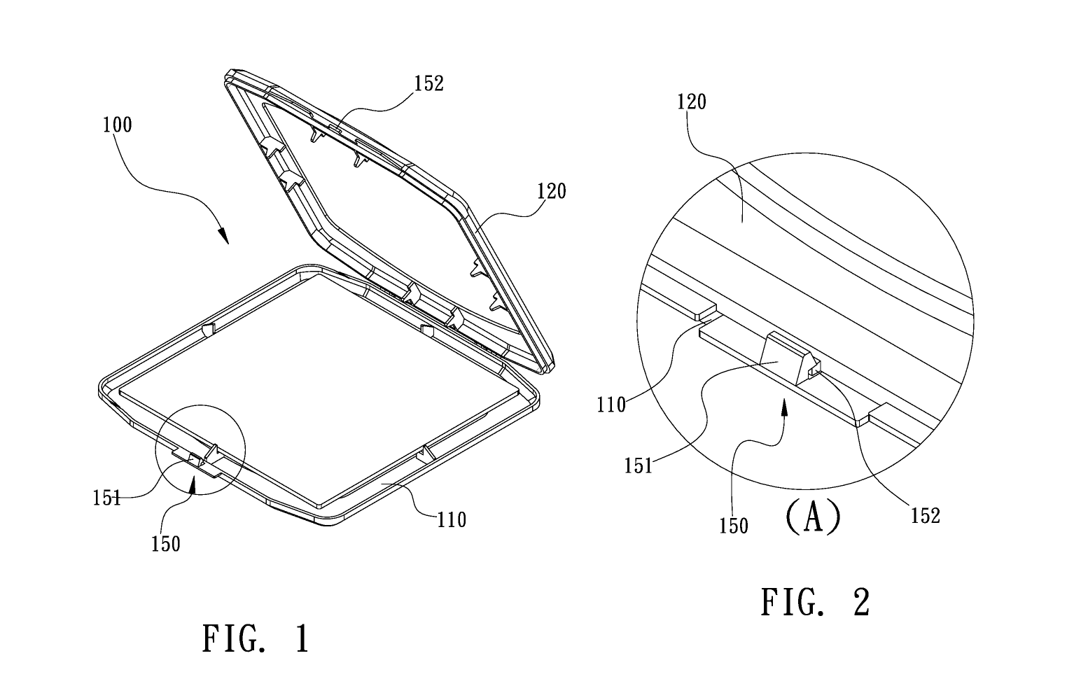

### DETAILED DESCRIPTION OF PREFERRED EMBODIMENT

As described in the RELATED PRIOR ART, a typical snap-shot case 100 includes a first shell 110 and a second shell 120. An edge of the first shell 110 is pivotally connected to an edge of the second shell 120 so that the first and second shells 110 and 120 can be pivoted to and from each other to close and open the snap-shot case 100. A snap-shot lock 150 is used to lock the first and second shells 110 and 120 to each other. The snap-shot lock 150 includes an elastic hook 151 formed at an opposite edge of the first shell 110 and a tab 152 formed at an opposite edge of the second shell 120. The snap-shot case 100 can be opened by a case-opening apparatus according to the preferred embodiment of the present invention.

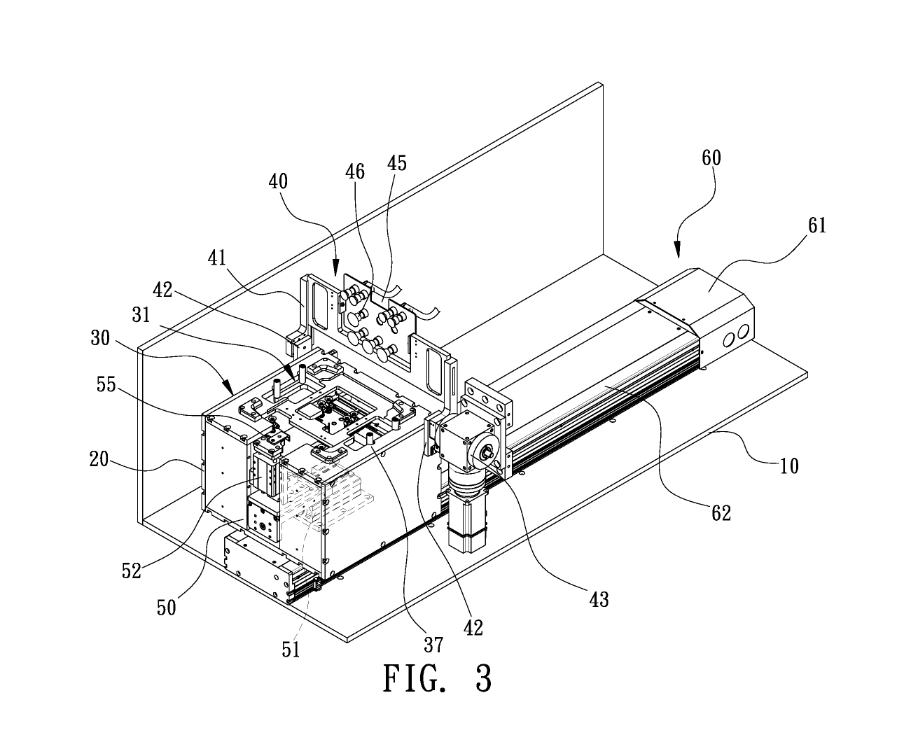

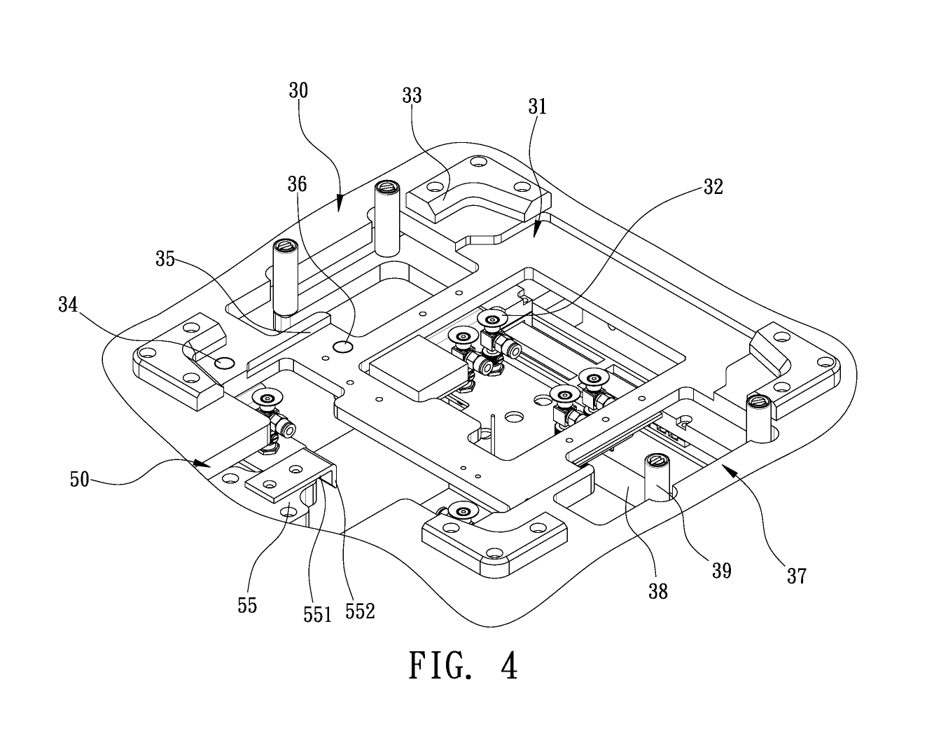

Referring to FIGS. 3 and 4, the case-opening apparatus includes a platform 10, a supporting element 20, a holding unit 30, a lifting unit 40 and a key-operating unit 50. The holding unit 30, the lifting unit 40 and the key-operating unit 50 are supported on the supporting element 20, which is supported on the platform 10.

In another embodiment, the case-opening apparatus further includes a feeder 60, and the supporting element 20 is supported on the feeder 60, which is supported on the platform 10. The feeder 60 can be used with an automatic optical inspection system (“AOI”), a mask-storing machine or a lithographic machine for example so that the feeder 60 can be operated to feed the mask to the AOI, the mask-storing machine or the lithographic machine from the snap-shot case 100. The feeder 60 includes a mover 61 and a track 62. The mover 61 is used to move the supporting element 20 along the track 62 in a direction X between a first position and a second position. The lifting unit 40 is located in the first or second position. The feeder 60 is used to move the supporting element 20 to or from the lifting unit 40.

Referring to FIGS. 3 and 4, the holding unit 30 includes a holder 31 and a clamp 37. Both of the holder 31 and the clamp 37 are used to hold the first shell 110 of the snap-shot case 100.

The h older 31 is used to hold a lower face of the first shell 110 of the snap-shot case 100. To this end, the holder 31 includes a plurality of sucking elements 32 for sucking the lower face of the first shell 110 of the snap-shot case 100.

The cl amp 37 is used to clamp the snap-shot case 100 by two opposite edges. The clamp 37 includes at least one driver 38 and at least one pair of claws 39. The driver 38 is used to close and open the pair of claws 39 in a direction Y to clamp and release the first shell 110 of the snap-shot case 100.

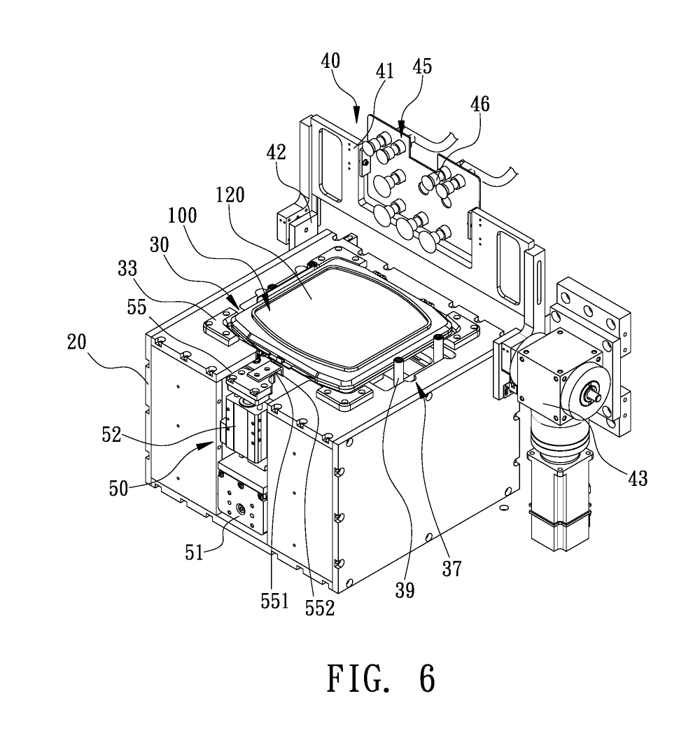

Referring to FIG. 6, the holding unit 30 can further include a first group of positioning elements 33 shaped and sized corresponding to corners or edges of the snap-shot case 100. The first group of positioning elements 33 guides the corners or edges of the snap-shot case 100 so that the snap-shot case 100 can be quickly located in the right position before it is sucked by the sucking elements 32. The holder 31 can father include a first sensor 34 used to determine whether the snap-shot case 100 is located in the right position.

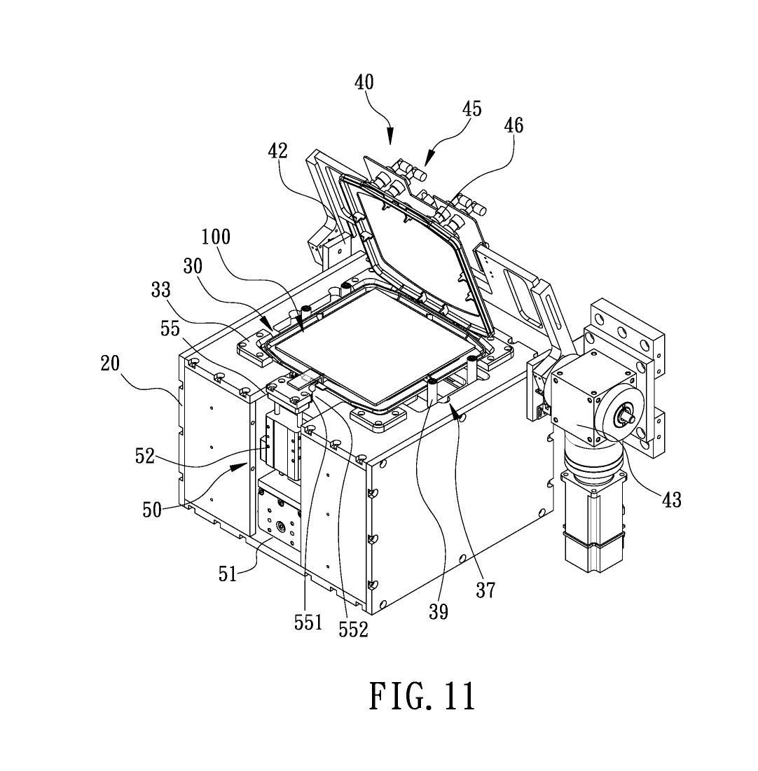

Referring to FIG. 11, the holding unit 30 can further include a second group of positioning elements 35 shaped and sized corresponding to a snap-shot case 100A of a different size. The second group of positioning elements 35 guides the corners or edges of the snap-shot case 100A so that the snap-shot case 100A can be quickly located in the right position before it is sucked by the sucking elements 32. The holding unit 30 can further include a second sensor 36 used to determine whether the snap-shot case 100A is located in the right position.

The lifting unit 40 is used to grasp and then lift the second shell 120 of the snap-shot case 100. The lifting unit 40 includes a plank 41 and a grasper 45. The plank 41 is pivotally connected to the platform 10 by two brackets 42. The lifting unit 40 can be pivoted relative to the holding unit 30, which is supported on the supporting element 20. The lifting unit 40 further includes an actuator 43 connected to at least one of the brackets 42. The actuator 43 is used to rotate the plank 41 for an angle θ. The grasper 45 is connected to the plank 41, and operable to grasp the second shell 120 of the snap-shot case 100. The grasper 45 includes a plurality of sucking elements 46 for sucking an upper face of the second shell 120 of the snap-shot case 100. After the sucking elements 46 of the grasper 45 suck the upper face of the second shell 120 of the supporting element 20, the actuator 43 pivots the plank 41 upward, thereby lifting the second shell 120 from the first shell 110.

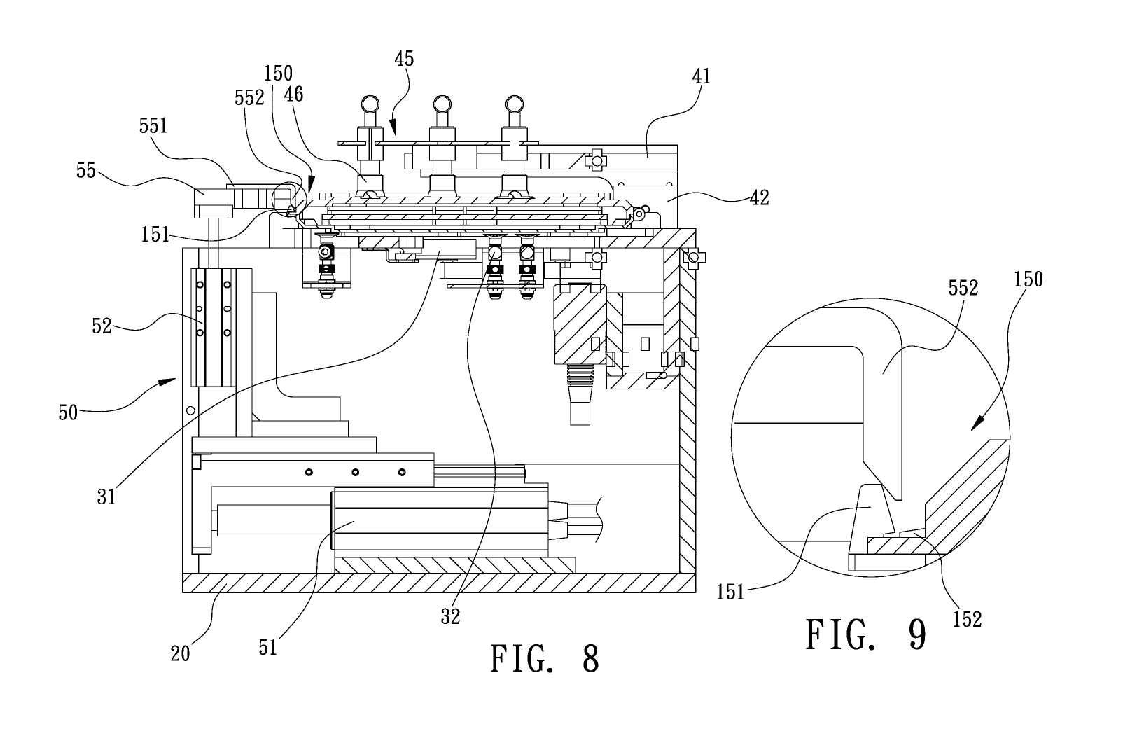

On th e supporting element 20, the key-operating unit 50 is located opposite to the lifting unit 40. The key-operating unit 50 includes a first driver 51, a second driver 52 and at least one key 55. The key 55 is supported on the second driver 52, which is connected to the first driver 51. The first and second drivers 51, 52 are used to move the key 55 in two directions X and Z, i.e., to move the key 55 relative to the elastic hook 151 of the snap-shot lock 150 to disengage the elastic hook 151 from the tab 152 referring to FIGS. 8 and 9. Thus, the snap-shot lock 150 is unlocked to allow the snap-shot case 100 to be opened. The key 55 can include an extensive strip 551 formed with a bent end 552. The bent end 552 of the extensive strip 551 is chamfered so that it contacts and pivots the elastic hook 151 of the snap-shot lock 150 when the key 55 is moved down relative to the snap-shot case 100. Hence, the elastic hook 151 is disengaged from the tab 152.

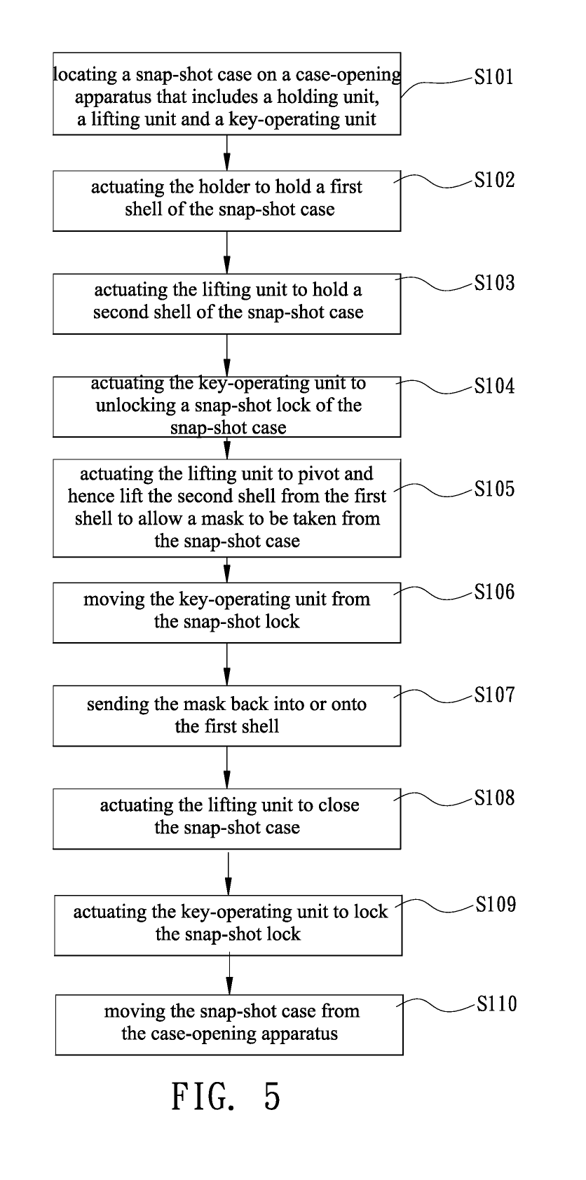

Referring to FIG. 5, there is a method for opening the snap-shot case 100. Referring to FIGS. 6 through 11, the case-opening apparatus is in different positions at different steps of the method.

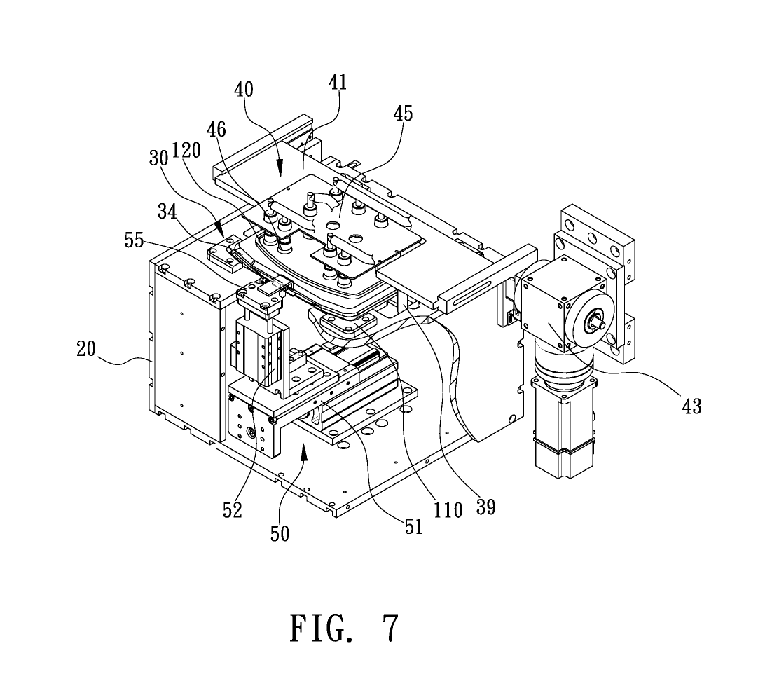

At S101, the snap-shot case 100 is located on the holding unit 30 of the case-opening apparatus. Referring to FIGS. 6 and 7, the first group of positioning elements 33 is used to facilitate efficient and precise positioning of the snap-shot case 100, and the first sensor 34 is actuated to detect whether if the snap-shot case 100 is in the right position

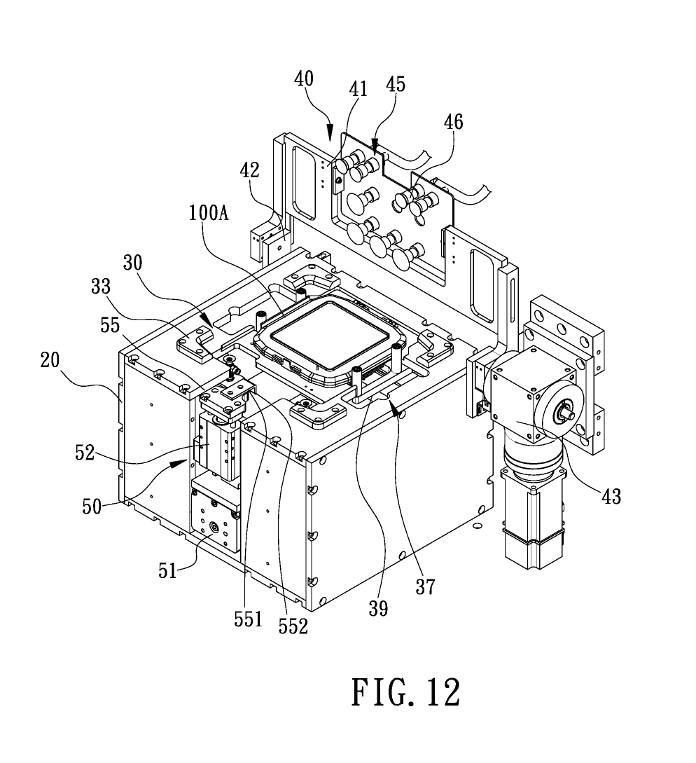

Referring to FIGS. 4 and 12, in addition, the second group of positioning elements 35 is used to facilitate efficient and precise positioning of the snap-shot case 100A. The second sensor 36 is actuated to detect whether if the snap-shot case 100A is in the right position.

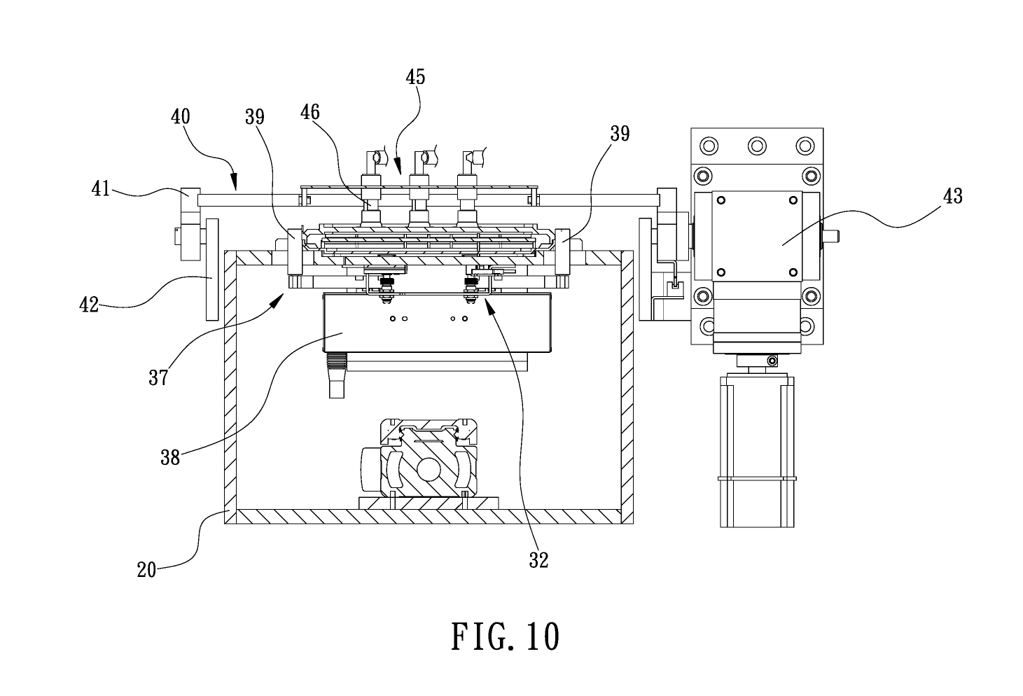

At S102, the holder 31 of the holding unit 30 is actuated to hold the first shell 110 of the snap-shot case 100. Referring to FIG. 8, the sucking elements 32 of the holder 31 of the holding unit 30 are actuated to suck the lower face of the first shell 110. Referring to FIG. 10, in addition, the claws 39 of the clamp 37 of the holding unit 30 are actuated to clamp the first shell 110 of the snap-shot case 100.

At S103, the lifting unit 40 is actuated to hold the second shell 102 of the snap-shot case 100. The lifting unit 40 is pivoted by the angle θ to a position above the second shell 120 of the snap-shot case 100. The grasper 45 of the lifting unit 40 is actuated to hold the second shell 120. In specific, referring to FIG. 8, the sucking elements 46 of the grasper 45 of the lifting unit 40 are actuated to suck the upper face of the second shell 110.

Alternatively, the holding unit 30 is supported on the supporting element 20 and the supporting element 20 is supported on the feeder 60. Hence, the feeder 60 moves the holding unit 30 in the direction X to a position below the lifting unit 40 before the lifting unit 40 is actuated to hold the second shell 120 of the snap-shot case 100.

At S104, the snap-shot lock 150 of the snap-shot case 100 is unlocked after the first and second shells 110 and 120 are respectively held by the holding unit 30 and the lifting unit 40. Referring to FIGS. 6 and 7, the key-operating unit 50 is moved to the snap-shot lock 150 of the snap-shot case 100. Then, referring to FIG. 9, the bent end 552 of the extensive strip 551 of the key 55 is actuated to pivot and hence disengage the elastic hook 151, which is formed on first shell 110, from the tab 152, which is formed on the second shell 120.

At S105, the lifting unit 40 is actuated to pivot and hence lift the second shell 120 from the first shell 110 so that an object such as a mask can be taken from the snap-shot case 100. Referring to FIG. 11, the lifting unit 40 is actuated to lift the second shell 120 from the first shell 110 after the elastic hook 151 is disengaged from the tab 152. The lifting unit 40 is pivoted to lift the second shell 120 from the first shell 110 because the first shell 110 is held by the holding unit 30.

At S106, the key-operating unit 50 is moved from the snap-shot lock 150. The first and second drivers 51, 52 are actuated to move the key 55 of the key-operating unit 50 from the snap-shot lock 150 after the key 55 of the key-operating unit 50 unlocks the snap-shot lock 150. Thus, the movement of the mask from the snap-shot case 100 is not hindered.

The mask is processed such as cleaned or optically inspected after it is taken from the snap-shot case 100. The following process can be executed after the mask is processed.

At S107, the mask is sent back into or onto the first shell 110 of the snap-shot case 100. For example, a robot can be used to send the mask back into or onto the first shell 110 of the snap-shot case 100.

At S108, the lifting unit 40 is actuated to close the snap-shot case 100. In specific, the lifting unit 40 is actuated to pivot the second shell 120 to the first shell 110 which is held by the holding unit 30.

At S109, the key-operating unit 50 is actuated to lock the snap-shot lock 150. The elastic hook 151 is just in contact with the tab 152, not engaged with each other yet, after the second shell 120 is pivoted to the first shell 110. The extensive strip 551 of the key 55 of the key-operating unit 50 is moved to the upper face of the second shell 120 of the snap-shot case 100. Then, the extensive strip 551 of the key 55 is moved downward to push the second shell 120 further toward the first shell 110, thereby moving the tab 152 against the elastic hook 151 so that the elastic hook 151 is engaged with the tab 152 again. Hence, the mask is locked in and protected by the snap-shot case 100.

At S110, the snap-shot case 100 is moved from the case-opening apparatus. After the snap-shot lock 150 is locked, the grasper 45 of the lifting unit 40 releases the second shell 120, and the lifting unit 40 is pivoted and hence lifted from the second shell 120. The holder 31 of the holding unit 30 releases the first shell 110. Then, the robot is actuated to move the snap-shot case 100 from the case-opening apparatus.

Advantageously, the holding unit 30 holds the first shell 110, the lifting unit 40 holds and lifts the second shell 120, and the key-operating unit 50 unlocks the snap-shot lock 150 to allow the lifting unit 40 to lift the second shell 120. Thus, the opening of the snap-shot case 100 is automated. Moreover, the closing of the snap-shot case 100 is automated. The opening and closing of the snap-shot case 100 is automatic, efficient and inexpensive, and the mask is kept clean during the opening and closing of the snap-shot case 100.

The present invention has been described via the illustration of the preferred embodiment. Those skilled in the art can derive variations from the preferred embodiment without departing from the scope of the present invention. Therefore, the preferred embodiment shall not limit the scope of the present invention defined in the claims.

1. A case-opening apparatus for opening a snap-shot case (100) that comprises a first shell (110), a second shell (120) pivotally connected to the first shell (110), a tab (152) formed on one of the first and second shells (120), and an elastic hook (151) formed on the other one of the first and second shells (110) and engageable with the tab (152), the case-opening apparatus comprising:
a holding unit (30) comprising a holder (31) for holding the first shell (110);
a lifting unit (40) located above the holding unit (30) and comprising a pivotable plank (41) and a grasper (45) connected to the pivotable plank (41) and operable to grasp the second shell (120); and
a key-operating unit (150) located in the vicinity of the holding unit (30) and comprising a key (151) operable to pivot the elastic hook (151) relative to the tab (152).

2. The case-opening apparatus according to claim 1, wherein the holder (31) comprises a plurality of sucking elements (32) operable to suck a lower face of the first shell, wherein the grasper (45) comprises a plurality of sucking elements (46) operable to suck an upper face of the second shell (120).

3. The case-opening apparatus according to claim 1, wherein the holding unit (30) further comprises a clamp (37) operable for clamping the first shell (110).

4. The case-opening apparatus according to claim 3, wherein the clamp (37) comprises at least two claws (39) and a driver (38) for moving the claws (39) toward each other to clamp the first shell (110).

5. The case-opening apparatus according to claim 1, wherein the holding unit (30) further comprises first group of positioning elements (33) corresponding to corners of the first shell.

6. The case-opening apparatus according to claim 1, further comprising a platform (10) for supporting the holding unit (30), the lifting unit (40) and the key-operating unit (150), wherein the lifting unit (40) further comprises a plank (41) for supporting the grasper (45), two brackets (42) for pivotally connecting the plank (41) to the platform (10), and an actuator (43) for pivoting the plank (41).

7. The case-opening apparatus according to claim 6, further comprises a supporting element (20) movable on the platform (10) between a first position and a second position, wherein the holding unit (30) and the key-operating unit (50) are supported on the supporting element (20), wherein the lifting unit (40) is located at one of the first and second positions of the supporting element (20).

8. The case-opening apparatus according to claim 1, wherein the key-operating unit (50) further comprises a first driver (51) and a second driver (52), wherein the key (55) is connected to the second driver (52), wherein the first and second drivers (51, 52) are operable to move the key (55) relative to the elastic hook (151).

9. The case-opening apparatus according to claim 8, wherein the key (55) comprises a bent end (552) for pivoting and hence disengaging the elastic hook (151) from tab (152).

10. A method for opening a snap-shot case (100) that comprises a first shell (110), a second shell (120) pivotally connected to the first shell (110), a tab (152) formed on one of the first and second shells (120), and an elastic hook (151) formed on the other one of the first and second shells (110) and engageable with the tab (152), the case-opening method comprising the steps of:
providing a case-opening apparatus with a holding unit (30), a lifting unit (40) and a key-operating unit (150);
locating the snap-shot case (100) on the case-opening apparatus;
actuating the holding unit (30) to hold the first shell (110);
actuating the lifting unit (40) to hold the second shell (120);
actuating the key-operating unit (50) to disengage the elastic hook (151) from the tab (152); and
actuating the lifting unit (40) to lift the second shell (120) from the first shell (110).

11. The method according to claim 10, wherein the holding unit (30) and the lifting unit (40) are actuated to produce vacuum to suck the first and second shells (110, 120).

12. The method according to claim 10, further comprising the step of moving the key-operating unit (50) from the snap-shot lock (150) not to interfere with the lifting of the second shell (120) and taking an object from the opened snap-shot case (100) after the step of actuating the lifting unit (40) to lift the second shell (120) from the first shell (110).
